(19) United States
(12) Patent Application Publication
(10) Pub. No.: US 2012/0168843 A1
(43) Pub. Date: Jul. 5, 2012

(54) SEMICONDUCTOR DEVICE AND FABRICATION METHOD THEREOF

(76) Inventor: Dae-Young SEO, Gyeonggi-do (KR)

(21) Appl. No.: 13/197,356

(22) Filed: Aug. 3, 2011

(30) Foreign Application Priority Data
Dec. 31, 2010 (KR) 10-2010-0140489

(51) Int. Cl. H01L 29/788; H01L 21/336

(52) U.S. Cl. 257/316; 438/266; 257/E29.3; 257/E21.422

(57) ABSTRACT

A semiconductor device includes a bit line formed over a substrate, an insulation layer formed over the bit line, a gate line crossing the bit line and formed over the insulation layer, and a channel layer formed on both sidewalls of the gate line and coupled to the bit line.

### CROSS-REFERENCE TO RELATED APPLICATIONS

The present application claims priority of Korean Patent Application No. 10-2010-0140489, filed on Dec. 31, 2010, which is incorporated herein by reference in its entirety.

### BACKGROUND

1. Field

Exemplary embodiments of the present invention relate to a method for fabricating a semiconductor device, and more particularly, to a semiconductor device having vertical channels, and a method for fabricating the semiconductor device.

2. Description of the Related Art

A Dynamic Random Access Memory (DRAM) device having a two-dimensional (2D) structure is reaching structural limitations with the increase of the integration degree thereof. Therefore, a three-dimensional (3D) DRAM device having vertical gates (VG) has been developed, which may be referred to as a VG DRAM.

A 3D DRAM device having vertical gates includes a body, an active region formed in the shape of a pillar over the body, a buried bit line (BBL), and a vertical gate (VG). Neighboring active regions are isolated by trenches, and the buried bit line fills a portion of each trench. The buried bit line is electrically connected to any one sidewall of the body. The vertical gate is formed on the sidewall of the pillar over the buried bit line, and a source region and a drain region are formed in the pillar. The vertical gate forms a vertical channel between the source region and the drain region.

A One-Side-Contact (OSC) process is performed to assign a cell for a buried bit line. The OSC process may be referred to as a Single-Side-Contact (SSC) process as well. Hereafter, the OSC process is referred to as a side contact forming process. The side contact forming process may be a process for forming a side contact between a bit line and one of adjacent active regions, while the other active region is insulated from the bit line. In this instance, the side contact is a bit line contact.

FIG. 1 illustrates a conventional semiconductor device.

Referring to FIG. 1, a plurality of active regions 13 isolated from each other by a trench 12 are formed over a substrate 11. A hard mask layer 14 is formed over the active regions 13. An insulation layer 15 is formed on the sidewalls of each active region 13, and the insulation layer 15 is patterned to expose a portion of one sidewall of the active region 13. The exposed portion is called a side contact. A buried bit line 17 is formed to be coupled with the active region 13 through the side contact. The buried bit line 17 fills a portion of the trench 12.

The conventional semiconductor device, however, has a high aspect ratio of the active regions 13. Therefore, the process for forming the side contact is complicated, and it is difficult to secure uniform side contact characteristics. After all, the electrical characteristics of the semiconductor device may be deteriorated.

### SUMMARY

An embodiment of the present invention is directed to a semiconductor device and a fabrication method thereof which may perform a bit line patterning easily without a bit line contact and increase channel efficiency.

In accordance with an embodiment of the present invention, a semiconductor device includes: a bit line formed over a substrate; an insulation layer formed over the bit line; a gate line crossing the bit line and formed over the insulation layer; and a channel layer formed on both sidewalls of the gate line and coupled to the bit line.

In accordance with another embodiment of the present invention, a method for fabricating a semiconductor device includes: forming a first insulation layer over a substrate; forming a bit line over the first insulation layer; forming a second insulation layer over the bit line; forming a gate line crossing the bit line over the second insulation layer; and forming a channel layer coupled to the bit line on both sidewalls of the gate line.

### BRIEF DESCRIPTION OF THE DRAWINGS

FIG. 1 is a cross-sectional view illustrating a conventional semiconductor device.

FIG. 2 is a cross sectional view illustrating a semiconductor device in accordance with an embodiment of the present invention.

FIGS. 3A to 3I are cross sectional views describing a method for fabricating a semiconductor device in accordance with an embodiment of the present invention.

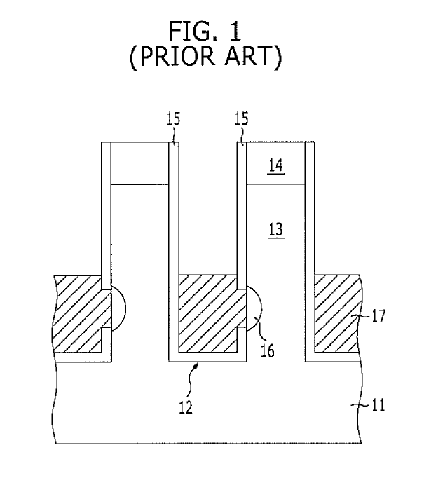

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

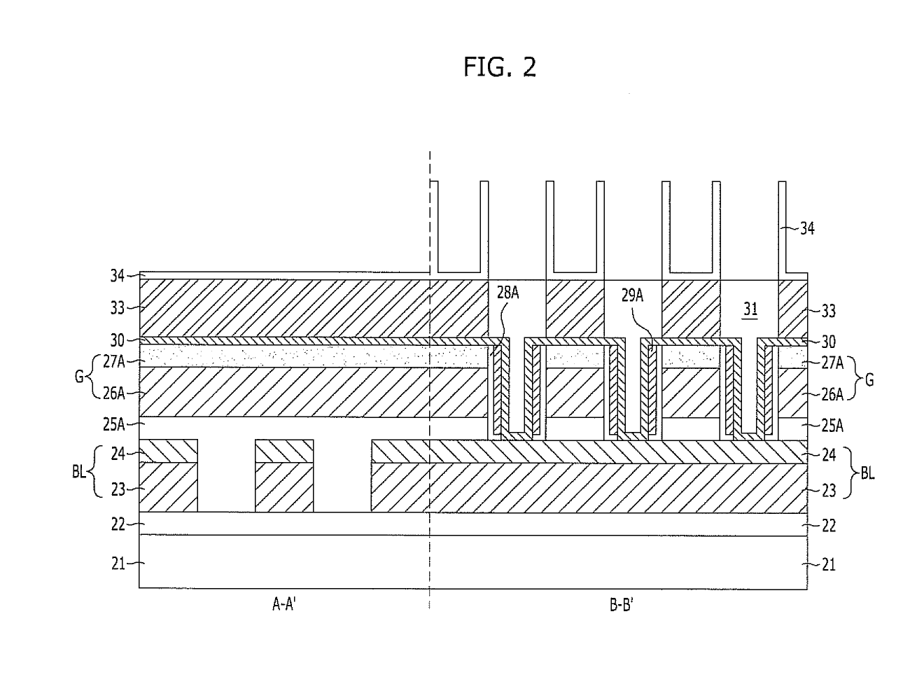

FIG. 2 is a cross sectional view illustrating a semiconductor device in accordance with an embodiment of the present invention. Here, a left section A-A′ of FIG. 2 illustrates a cross sectional view of the semiconductor device taken along a gate line thereof, while a right section B-B′ of FIG. 2 illustrates one taken along a bit line.

Referring to FIG. 2, a first insulation layer 22 is formed over a substrate 21, and bit lines BL are formed over the first insulation layer 22. The bit lines BL is a stacked layer of a metal layer 23 and a polysilicon layer 24.

A second insulation layer pattern 25A is formed over the bit lines BL, and a gate electrode 26A is formed over the second insulation layer pattern 25A. A gate hard mask layer 27A is formed over the gate electrode 26A. Subsequently, channel layers coupled to the bit lines BL are formed on both sidewalk of the gate electrode 26A. The channel layers include a first channel layer 29A and a second channel layer 30. The first channel layer 29A is formed on both sidewalls of the gate electrode 26A, and the second channel layer 30 covers the sidewall of the first channel layer 29A and is coupled to the bit lines BL at its ends. The second channel layer 30 covers the surface of the gate hard mask layer 27A. The semiconductor device includes a contact plug 33 coupled to the second channel layer 30. Also, the semiconductor device includes a storage node 34 coupled with the contact plug 33. The contact plug 33 fills a contact hole (not shown with a reference numeral) formed in an inter-layer dielectric layer 31 and is coupled with the second channel layer 30.

The structure where the gate electrode 26A and the gate hard mask layer 27A are stacked forms a gate line G. The semiconductor device further includes a gate insulation layer pattern 28A formed between both sidewalls of the gate line G and the first channel layer 29A. The bit lines BL and the gate line G cross each other. According to one embodiment, the bit lines BL and the gate line G cross each other at a right angle.

Referring to FIG. 2, the gate electrode 26A is formed over the bit lines BL, and the gate electrode 26A and the bit lines BL cross each other at a right angle. Also, the first and second channel layers 29A and 30 are formed on both sidewalls of the gate electrode 26A. Accordingly, the first and second channel layers 29A and 30 form channels in a vertical direction. Moreover, the first and second channel layers 29A and 30 form the channels at both sides of the gate electrode 26A.

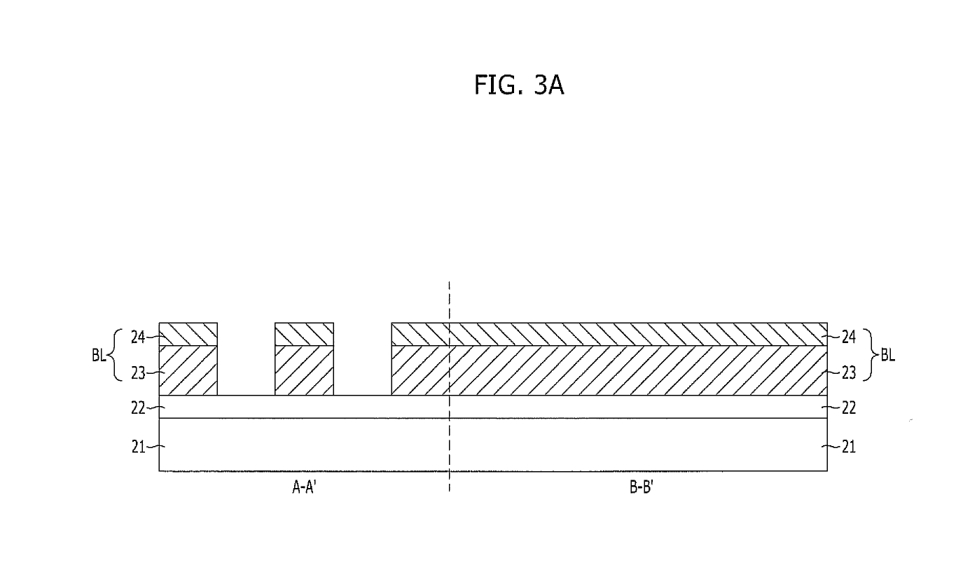

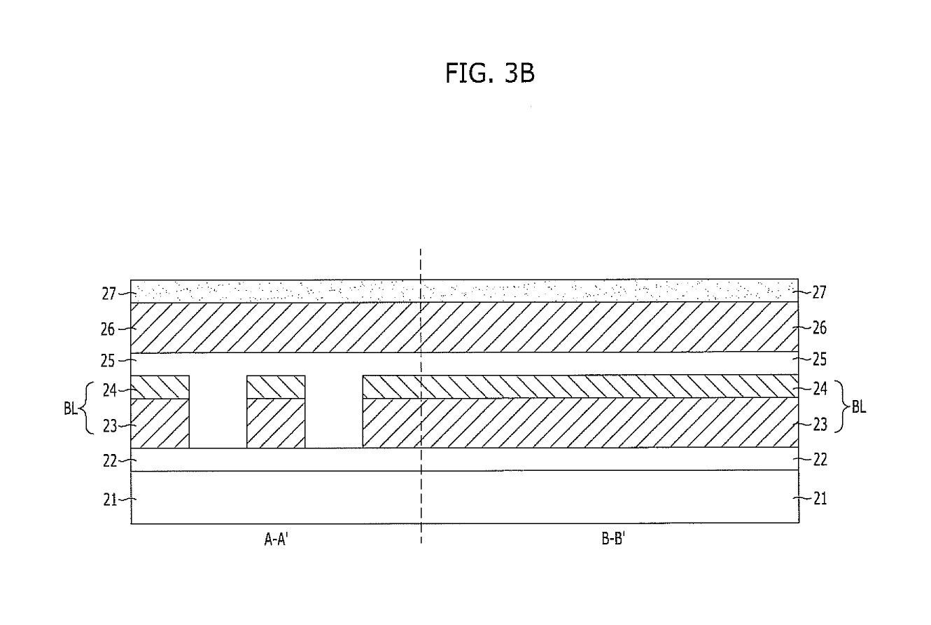

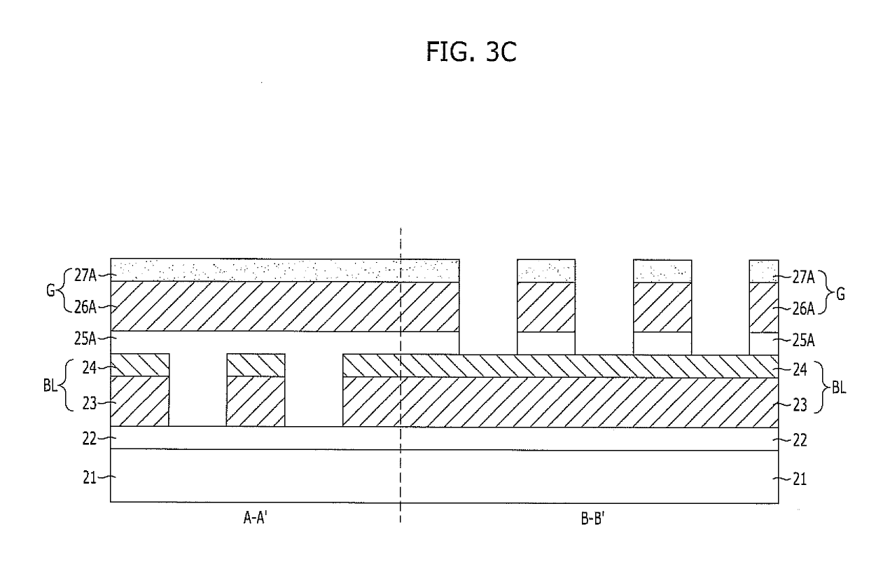

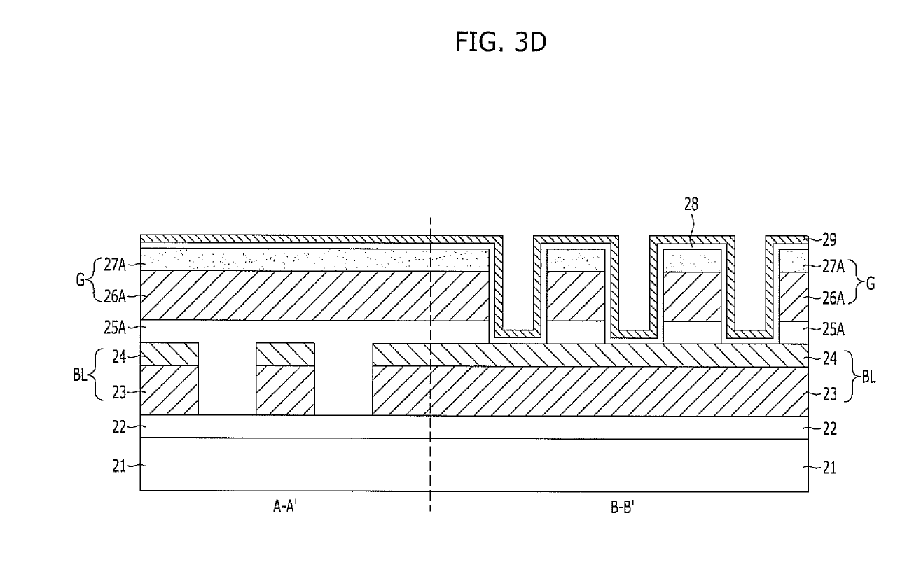

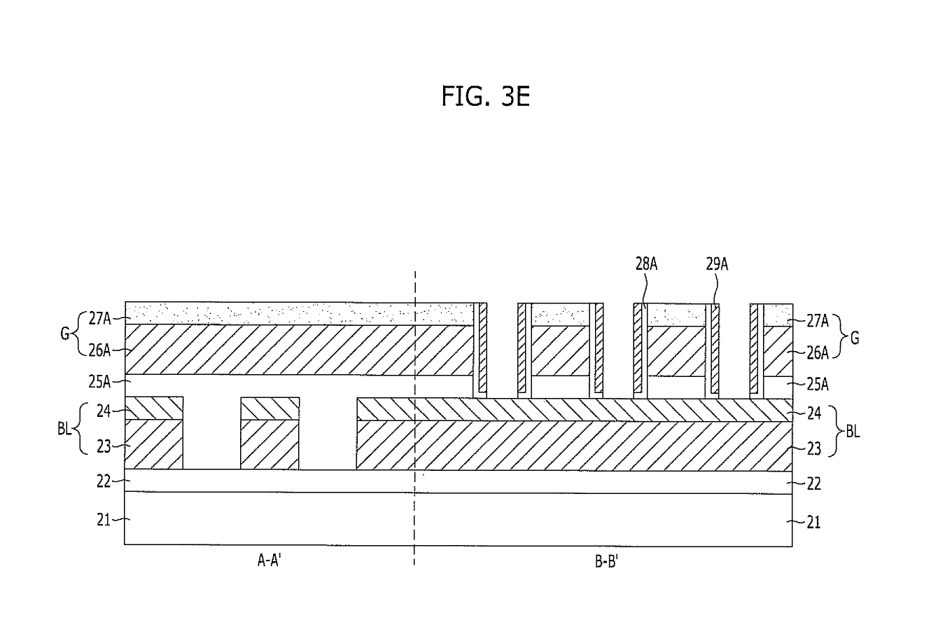

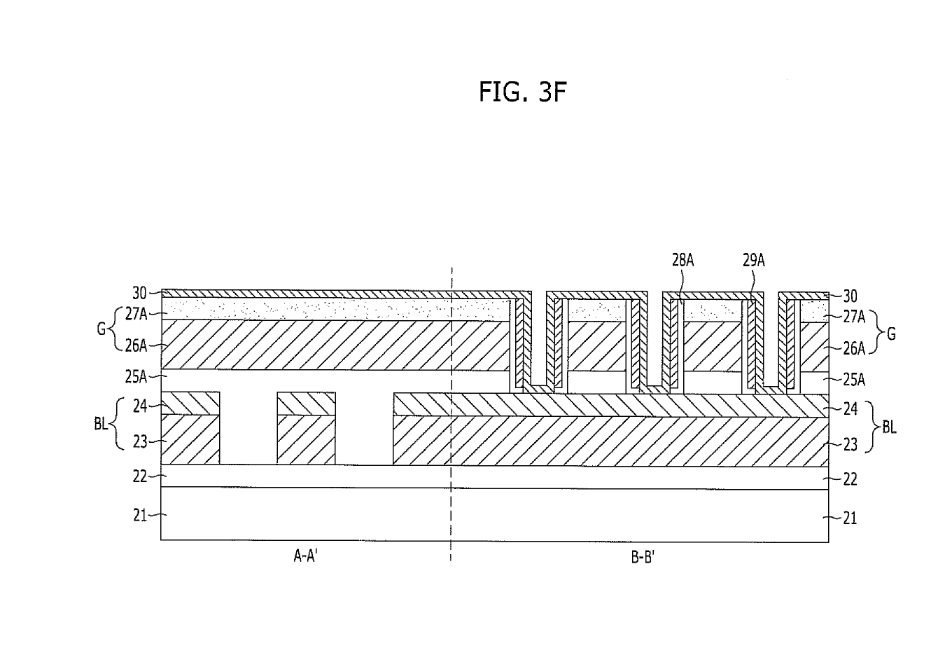

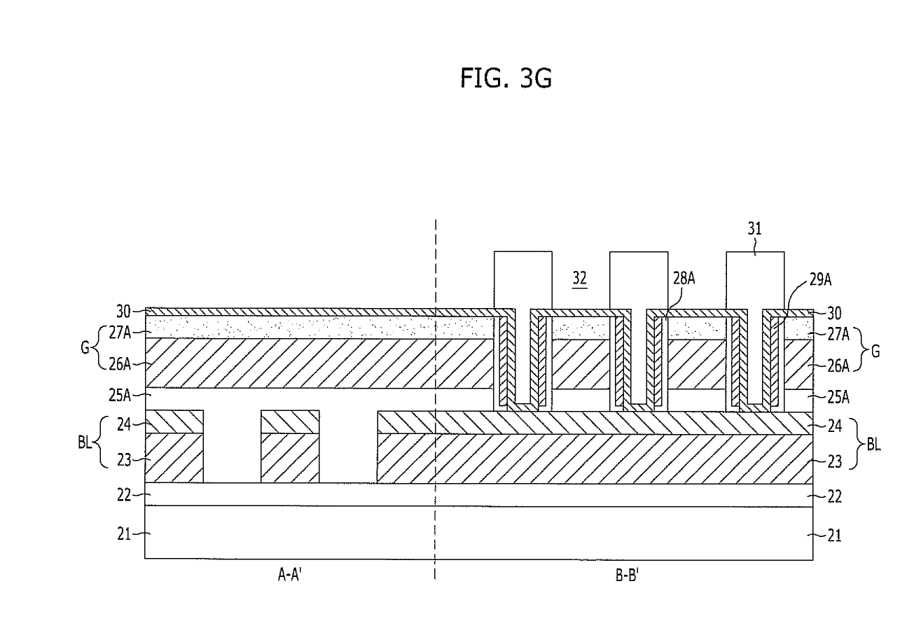

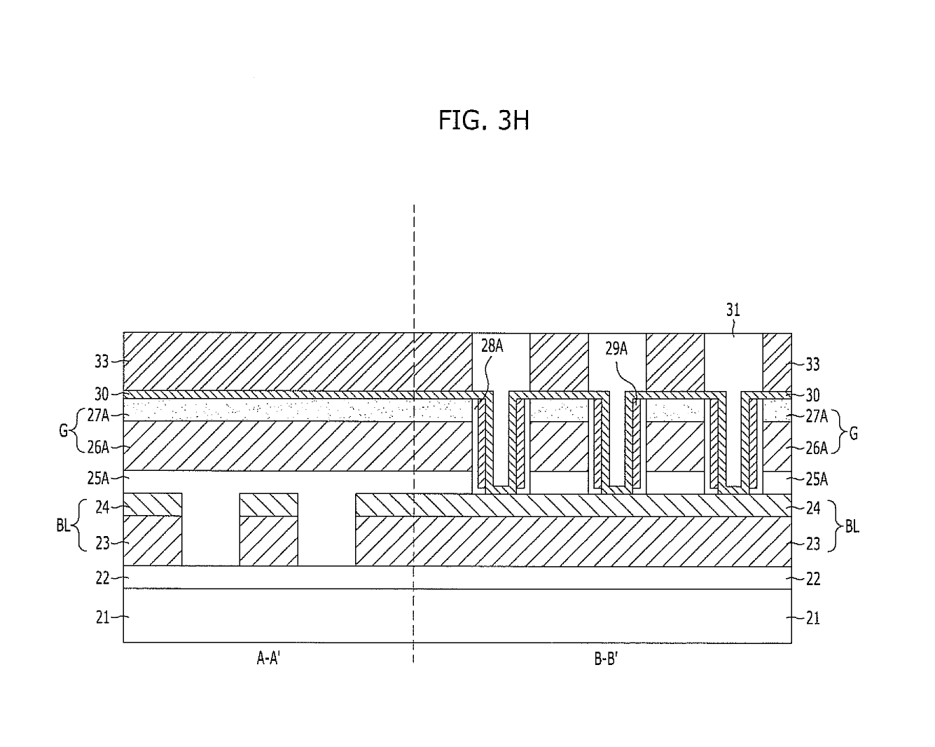

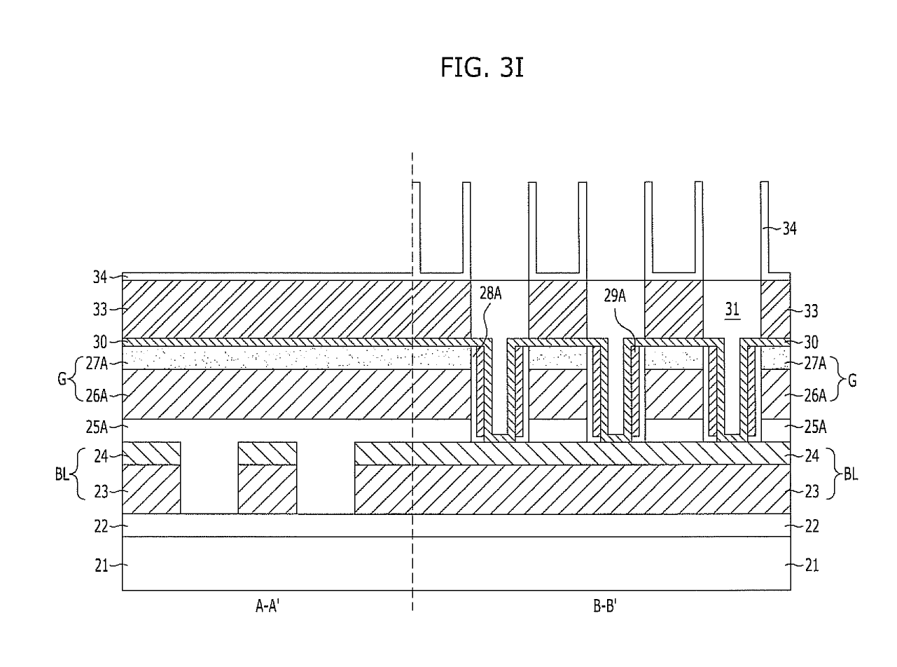

FIGS. 3A to 3I are cross sectional views describing a method for fabricating a semiconductor device in accordance with an embodiment of the present invention. Here, a left section A-A′ of FIGS. 3A to 3I illustrates a cross sectional view of the semiconductor device taken along a gate line thereof, while a right section B-B′ of FIGS. 3A to 3I illustrates one taken along a bit line.

Referring to FIG. 3A, a first insulation layer 22 is formed over a substrate 21. The substrate 21 may be a silicon substrate. The first insulation layer 22 may be an oxide layer, such as a silicon oxide layer.

A first conductive layer is formed over the first insulation layer 22. The first conductive layer is formed by stacking a metal layer 23 and a polysilicon layer 24. The metal layer 23 may be a tungsten layer. The polysilicon layer 24 may be a doped polysilicon layer, for example, a polysilicon layer doped with an N-type impurity. A single polysilicon layer doped with an N-type impurity may be used as the first conductive layer.

Subsequently, bit lines BL are formed by patterning the first conductive layer. As a result, the bit lines BL are extended in one direction, e.g., the B-B′ direction. The bit lines BL have a structure where the metal layer 23 and the polysilicon layer 24 are stacked.

Referring to FIG. 3B, a second insulation layer 25 is formed over the substrate structure including the bit lines BL. The second insulation layer 25 is planarized by performing a Chemical Mechanical Polishing (CMP) process. The second insulation layer 25 serves as an inter-layer dielectric layer between the bit lines BL and the gate lines G. The thickness of the second insulation layer 25 is controlled at a proper level. In this way, a gate electrode may easily control channels. According to an embodiment of the present invention, the second insulation layer 25 is formed to have a thickness ranging from approximately 100 Å to approximately 300 Å. When the second insulation layer 25 is thinner than approximately 100 Å, interference occurs between the bit lines BL and the gate lines. When the second insulation layer 25 is thicker than approximately 300 Å, it is difficult to control channels.

A second conductive layer 26 is formed over the second insulation layer 25. The second conductive layer 26 is a material used as a gate electrode. The second conductive layer 26 may be a metal layer or a polysilicon layer. Also, the second conductive layer 26 may be formed by stacking a metal layer and a polysilicon layer.

Subsequently, a hard mask layer 27 is formed over the second conductive layer 26. The hard mask layer 27 may be a nitride layer such as a silicon nitride layer. The thickness of the hard mask layer 27 is controlled at a proper level. In this way, a gate electrode may easily control channels. According to an embodiment of the present invention, the hard mask layer 27 is formed to have a thickness ranging from approximately 100 Å to approximately 300 Å. When the hard mask layer 27 is thinner than approximately 100 Å, interference occurs between a gate electrode and contact plugs. When the hard mask layer 27 is thicker than approximately 300 Å, it is difficult to control channels. The hard mask layer 27 becomes a gate hard mask layer through a subsequent process.

Referring to FIG. 3C, a gate electrode 26A is formed by patterning the second conductive layer 26. The second conductive layer 26 may be patterned using a photoresist layer, which is a gate mask (not shown). First, the hard mask layer 27 is etched to thereby form the gate hard mask layer 27A, and then the second conductive layer 26 is etched using the gate hard mask layer 27A as an etch barrier. The second conductive layer 26 is patterned along a direction crossing the bit lines BL at a right angle. After the second conductive layer 26 is etched, the second insulation layer 25 is etched. For example, the second insulation layer 25 is etched along the A-A′ direction to form a second insulation layer pattern 25A. As a result, bit lines BL and the gate electrode 26A are formed to cross each other at a right angle.

Consequently, a semiconductor device has a structure where the gate electrode 26A is formed over the bit lines BL. The structure where the gate electrode 26A and the gate hard mask layer 27A are stacked is referred to as a gate line G.

Referring to FIG. 3D, a gate insulation layer 28 is formed over the substrate structure including the gate hard mask layer 27A. The gate insulation layer 28 may be a silicon oxide layer. Also, the gate insulation layer 28 may be formed of a high dielectric material.

A third conductive layer 29 is formed over the gate insulation layer 28. The third conductive layer 29 may be a polysilicon layer and it may be formed thin. The third conductive layer 29 may be any one selected from the group consisting of an undoped polysilicon layer, a polysilicon layer doped with a P-type impurity, and a polysilicon layer doped with an N-type impurity.

Referring to FIG. 3E, the third conductive layer 29 and the gate insulation layer 28 are etched. For example, an etch-back process may be performed and as a result of the process, a first channel layer 29A and a gate insulation layer pattern 28A remain on the sidewalls of the gate electrode 26A. The first channel layer 29A and the gate electrode 26A form channels in the vertical direction. The first channel layer 29A and the gate insulation layer pattern 28A remain on the sidewalls of the gate hard mask layer 27A and the second insulation layer pattern 25A.

When the third conductive layer 29 and the gate insulation layer 28 are etched through the etch-back process, the upper surface of the bit lines BL is exposed partially.

Referring to FIG. 3F, a fourth conductive layer 30 is formed. The fourth conductive layer 30 may be a polysilicon layer. The fourth conductive layer 30 may be any one selected from the group consisting of an undoped polysilicon layer, a polysilicon layer doped with a P-type impurity, and a polysilicon layer doped with an N-type impurity. The fourth conductive layer 30 is coupled with the first channel layer 29A, and it is insulated from the gate electrode 26A by the gate insulation layer pattern 28A and the gate hard mask layer 27A. Also, the fourth conductive layer 30 is coupled with the bit lines BL. After all, the fourth conductive layer 30 and the bit lines BL are directly coupled with each other without contact plugs. Since the fourth conductive layer 30 becomes channels, the fourth conductive layer 30 is referred to as a second channel layer 30, hereafter.

Referring to FIG. 3G, a third insulation layer 31 is formed over the second channel layer 30. The third insulation layer 31 may be a silicon oxide layer.

The third insulation layer 31 is patterned to thereby form contact holes 32. The contact holes 32 expose a portion of the surface of the second channel layer 30. According to an embodiment of the present invention, the contact holes 32 expose a portion of the second channel layer 30 over the gate hard mask layer 27A.

Referring to FIG. 3H, contact plugs 33 filling the contact holes 32 are formed. Here, the contact plugs 33 become storage node contact plugs. The contact plugs 33 are formed by depositing polysilicon and performing a CMP process or an etch-back process.

Referring to FIG. 3I, a storage node 34 is formed over the contact plug 33. The storage node 34 has a cylindrical shape. According to another embodiment of the present invention, the storage node 34 may have a pillar shape.

According to the embodiment of the present invention, the semiconductor device has both side channels of a vertical structure in which a channel layer is formed on both sidewalls of the gate electrode 26A. As a result, the area of a channel is increased twice, thereby increasing channel efficiency.

Since the bit line contact forming process, which has high process complexity, is omitted in the method for forming a semiconductor device in accordance with an embodiment of the present invention, the fabrication process is simplified, thereby reducing production cost with a low defect rate and a high throughput.

Also, since bit lines are formed over a substrate, patterning the bit lines may be performed easily.

Furthermore, since both side channels are formed in a vertical structure by using a channel layer formed on both sidewalls of a gate electrode, channel efficiency may be increased.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a bit line formed over a substrate;
an insulation layer formed over the bit line;
a gate line crossing the bit line and formed over the insulation layer; and
a channel layer formed on both sidewalls of the gate line and coupled to the bit line.

2. The semiconductor device of claim 1, wherein the channel layer comprises:
a first channel layer formed on said both sidewalls of the gate line; and
a second channel layer covering a sidewall of the first channel layer and a surface of the gate line and coupled to the bit line at ends thereof.

3. The semiconductor device of claim 2, further comprising:
a contact plug coupled with the second channel layer.

4. The semiconductor device of claim 3, further comprising:
a storage node coupled with the contact plug.

5. The semiconductor device of claim 1, wherein the gate line comprises a structure where a gate electrode and a gate hard mask layer are stacked.

6. The semiconductor device of claim 1, further comprising:
a gate insulation layer pattern formed between said both sidewalls of the gate line and the channel layer.

7. A method for fabricating a semiconductor device, comprising:
forming a first insulation layer over a substrate;
forming a bit line over the first insulation layer;
forming a second insulation layer over the bit line;
forming a gate line crossing the bit line over the second insulation layer; and
forming a channel layer coupled to the bit line on both sidewalls of the gate line.

8. The method of claim 7, wherein the forming of the bit line comprises:
forming a first conductive layer over the first insulation layer; and
patterning the first conductive layer.

9. The method of claim 8, wherein in the forming of the first conductive layer,
the first conductive layer is formed by stacking a metal layer and a polysilicon layer or the first conductive layer is formed of a polysilicon layer.

10. The method of claim 7, wherein the forming of the gate line comprises:
forming a second conductive layer over the second insulation layer;
forming a gate hard mask layer over the second conductive layer;
etching the gate hard mask layer and the second conductive layer; and
etching the second insulation layer to expose a portion of a surface of the bit line.

11. The method of claim 10, wherein in the forming of the second conductive layer,
the second conductive layer is formed by stacking a metal layer and a polysilicon layer or the second conductive layer is formed of a polysilicon layer.

12. The method of claim 7, wherein the forming of the channel layer comprises:
forming a third conductive layer over a substrate structure including the gate line;
performing an etch-back process on the third conductive layer; and
forming a fourth conductive layer over a substrate structure including the third conductive layer.

13. The method of claim 12, wherein in the performing of the etch-back process, the third conductive layer is etched to expose a surface of the gate line and a portion of a surface of the bit line.

14. The method of claim 13, wherein in the forming of the fourth conductive layer, the fourth conductive layer is formed to cover the surface of the gate line and be coupled to the bit line through the exposed portion.

15. The method of claim 12, wherein each of the third conductive layer and the fourth conductive layer is one selected from the group consisting of an undoped polysilicon layer, a polysilicon layer doped with an N-type impurity, and a polysilicon layer doped with a P-type impurity.

16. The method of claim 12, after the forming of the fourth conductive layer, further comprising:
forming a third insulation layer over the fourth conductive layer;
forming a contact hole that exposes a portion of a surface of the fourth conductive layer by etching the third insulation layer;
forming a contact plug in the contact hole; and
forming a storage node coupled with the contact plug.

17. The method of claim 7, wherein the second insulation layer is formed to have a thickness ranging from approximately 100 Å to approximately 300 Å.
